(19) United States
(12) Patent Application Publication
(10) Pub. No.: US 2022/0016874 A1
(43) Pub. Date: Jan. 20, 2022

(54) FLEXIBLE CONDUCTIVE FILM, PRODUCING METHOD THEREOF, AND DISPLAY PANEL

(71) Applicant: Shenzhen China Star Optelectronics Technology Co., Ltd., Shenzhen (CN)

(72) Inventors: Ying LI, Shenzhen (CN); Weiping LIU, Shenzhen (CN)

(21) Appl. No.: 16/496,442

(22) PCT Filed: Apr. 24, 2019
(86) PCT No.: PCT/CN2019/083978

§ 371 Date: Sep. 22, 2019

(30) Foreign Application Priority Data
Apr. 9, 2019 (CN) 201910280192.9

(51) Int. Cl. B32B 27/08; H01B 1/02; C09D 5/24; C09D 165/00; B32B 27/28; B32B 3/30; B32B 37/16

(52) U.S. Cl. CPC B32B 27/08; H01B 1/02; C09D 5/24; C09D 165/00; B32B 27/283; B32B 2383/00; B32B 37/16; B32B 2255/10; B32B 2255/26; B32B 2255/205; B32B 2457/20; B32B 3/30

(57) ABSTRACT

A method of producing a flexible conductive film includes: producing a bottom film and applying a pre-stretched stress on the bottom film; forming a conductive layer on the pre-stretched bottom film; and releasing the pre-stretched stress applied to the bottom film wherein the bottom film and the conductive layer are elastically contracted; the conductive layer and one side of the bottom film adjacent to the conductive layer shrink in a wave shape. The method of producing the flexible conductive film provided by the present disclosure can improve the flexibility and the stability of the conductive layer while the conductive layer is being used, thereby improving the service life of the flexible conductive film.

### BACKGROUND

### 1. Field of the Disclosure

The present disclosure relates to the field of optics, and more particularly, to a flexible conductive film, a method for producing the flexible conductive film, and a display panel.

### 2. Description of the Related Art

A flexible transparent conductive film has been widely adopted in the field of photovoltaic devices such as liquid crystal displays, touch panels, organic light emitting diodes, and solar cells in recent years owing to features such as electrical conductivity, light transmittance, and bending resistance. Common transparent conductive films are indium tin oxide (ITO) films, metal mesh film, Nano silver wire film and the like.

The technology of the ITO film is mature but the raw material cost of the ITO film is high, the conductivity of the ITO film is limited, and the ITO film is not resistant to bending. The price of the material for a metal mesh film is low and the metal mesh film is resistant to electromagnetic interference, but the metal wire is wide under Murray interference. The width of the silver nanowire is small. The conductive film with the silver nanowire has the advantages of low square resistance, high transmittance, and bending resistance. However, the transparency drops significantly after the number of nanowires increases to reduce the resistance value. Moreover, the silver nanowire flexible electrode of the related is mainly produced by transferring nanowires in parallel on a flexible substrate. Under external stress, the flexibility of the silver nanowires is limited, and the electrical properties and the service life of the electrodes are affected after the fracture occurs.

In summary, although the flexible conductive film of the related art has many advantages, some problems still occur to the flexible conductive film of the related art in flexible electronics in performance, reliability, and service life.

### SUMMARY

The present disclosure provides a flexible conductive film, a producing method for the flexible conductive film, and a display panel to deal with the technical problem that the flexible conductive film of the related art has poor stability and limited flexibility, thereby causing the reliability and life of the flexible conductive film to be affected.

According to the present disclosure, a method of producing a flexible conductive film includes:

a step S10 of producing a bottom film and applying a pre-stretched stress on the bottom film;

a step S20 of forming a conductive layer on the pre-stretched bottom film; and

a step of S30 of releasing the pre-stretched stress applied to the bottom film wherein the bottom film and the conductive layer are elastically contracted; the conductive layer and one side of the bottom film adjacent to the conductive layer shrink in a wave shape.

According to one embodiment of the present disclosure, the producing method further comprises a step of S40 of forming a protective layer on the conductive layer.

According to one embodiment of the present disclosure, the step S20 comprises: a step S201 of forming a first conductive layer on the pre-stretched bottom film; and a step S202 of forming a second conductive layer on the first conductive layer.

According to one embodiment of the present disclosure, a material for both of the first conductive layer and the second conductive layer is silver Nano, 3,4-ethylenedioxythiophene/polyphenylenesulfonic acid (PEDOT/PSS), or graphene oxide.

According to one embodiment of the present disclosure, the step S20 comprises: a step S201 of producing a silver nanowire and transferring the silver nanowire onto the pre-stretched bottom film to form the first conductive layer; and a step S202 of coating a mixture of 3,4-ethylenedioxythiophene (PEDOT) and polyphenylenesulfonic acid (PSS) on the bottom film and make the mixture dry to form the second conductive layer.

According to one embodiment of the present disclosure, the structure of and the material for the protective layer is the same as the structure and material for the bottom film.

According to one embodiment of the present disclosure, the material for the bottom film is either bisamino-polydimethylsiloxane (H2N-PDMS-NH2) or polyurethane elastomer.

According to the present disclosure, a flexible conductive film includes: a bottom film, and a conductive layer disposed on the bottom film. The conductive layer and one side of the bottom film near the conductive layer are both wavy.

According to one embodiment of the present disclosure, the conductive layer comprises a first conductive layer disposed on the bottom film and a second conductive layer disposed on the first conductive layer.

According to one embodiment of the present disclosure, the first conductive layer and the second conductive layer are both wavy.

According to one embodiment of the present disclosure, a material for both of the first conductive layer and the second conductive layer is silver Nano, 3,4-ethylenedioxythiophene/polyphenylenesulfonic acid (PEDOT/PSS), or graphene oxide.

According to one embodiment of the present disclosure, the flexible conductive film further comprises a protective layer disposed on the conductive layer.

According to one embodiment of the present disclosure, the structure of and the material for the protective layer is the same as the structure and material for the bottom film.

According to one embodiment of the present disclosure, the material for the bottom film is either bisamino-polydimethylsiloxane (H2N-PDMS-NH2) or polyurethane elastomer.

According to the present disclosure, a display panel includes a substrate and a flexible conductive film disposed on the substrate. The flexible conductive film includes a bottom film and a conductive layer, disposed on the bottom film. The conductive layer and one side of the bottom film near the conductive layer are both wavy.

According to one embodiment of the present disclosure, the conductive layer comprises a first conductive layer disposed on the bottom film and a second conductive layer disposed on the first conductive layer.

According to one embodiment of the present disclosure, the first conductive layer and the second conductive layer are both wavy.

According to one embodiment of the present disclosure, the flexible conductive film further comprises a protective layer disposed on the conductive layer.

According to one embodiment of the present disclosure, the structure of and the material for the protective layer is the same as the structure and material for the bottom film.

According to one embodiment of the present disclosure, the material for the bottom film is either bisamino-polydimethylsiloxane (H2N-PDMS-NH2) or polyurethane elastomer.

The present disclosure brings beneficial effects as follows. The method of producing the flexible conductive film provided by the present disclosure can improve the flexibility and the stability of the conductive layer while the conductive layer is being used, thereby improving the service life of the flexible conductive film.

### BRIEF DESCRIPTION OF THE DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 illustrates a flowchart of a method of producing a flexible conductive film according to an embodiment of the present disclosure.

FIG. 2 illustrates a flexible conductive film according to an embodiment of the present disclosure.

FIGS. 3-5 illustrate the structures of the flexible conductive film during the processes of the method as depicted in FIG. 1 according to a first embodiment of the present disclosure.

FIG. 6 illustrates a structure diagram of the flexible conductive film according to a second embodiment of the present disclosure.

### DETAILED DESCRIPTION OF THE EMBODIMENTS

In the description of the present disclosure, it should be understood that terms such as “center,” “longitudinal,” “lateral,” “length,” “width,” “thickness,” “upper,” “lower,” “front,” “rear,” “left,” “right,” “vertical,” “horizontal,” “top,” “bottom,” “inside,” “outside,” “clockwise,” “counter-clockwise” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure.

The shortcomings of a conductive film of the related art are poor stability and limited flexibility, which further affects the reliability and service life of the conductive film, which can be well dealt with by the present embodiment.

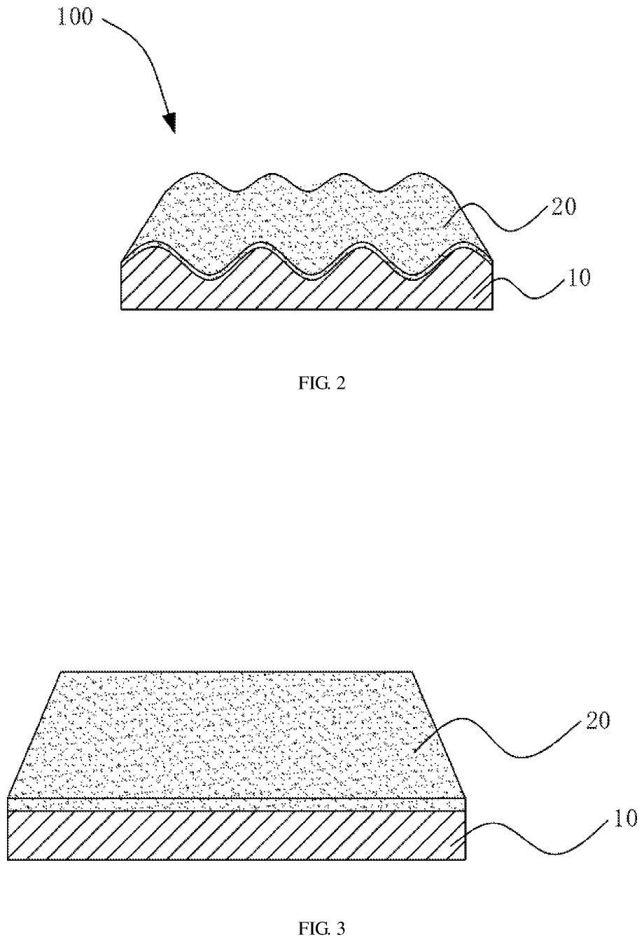

As FIG. 2 illustrates, the flexible conductive film 100 includes a bottom film 10 and a conductive layer 20. The conductive layer 20 is disposed on the bottom film 10. The conductive layer 20 and one side of the bottom film 10 near the conductive layer 20 are both wavy.

As FIG. 2 illustrates, the producing method of the flexible conductive film 100 includes Block S10 of producing a bottom film 10 and applying a pre-stretched stress on the bottom film 10, Block S20 of forming a conductive layer 20 on the pre-stretched bottom film 10, and Block S30 of releasing the pre-stretched stress applied to the bottom film 10. The bottom film 10 and the conductive layer 20 are elastically contracted. The conductive layer 20 and one side of the bottom film 10 near the conductive layer 20 are both shrunk and wavy.

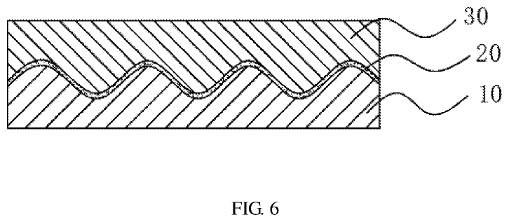

In FIG. 6, the flexible conductive film 100 further includes a protective layer 30 disposed on the conductive layer 20. The producing method further includes forming a protective layer 30 on the conductive layer 20 following Block S30.

The material for the protective layer 30 is the same as the material for the bottom film 10. The material for the bottom film 10 is a modified polydimethylsiloxane such as bisamino-polydimethylsiloxane (H2N-PDMS-NH2). The imine bond contained in the modified polydimethylsiloxane can be cured by Schiff base reaction at room temperature with polytriphenylaldehyde. Therefore, the bottom film 10 with cracks can be self-healed at room temperature to repair the cracks completely, which enhances the production yield of the flexible conductive film 100 and prolongs the service life of the flexible conductive film 100 to some extent.

Further, the material for the bottom film 10 may be a transparent polyurethane elastomer, which has better flexibility and transparency.

The material for the conductive layer 20 may be silver Nano, 3,4-ethylenedioxythiophene/polyphenylenesulfonic acid (PEDOT/PSS), or graphene oxide. Besides, the conductive layer 20 may be produced by any combinations of silver Nano, PEDOT/PSS, and graphene oxide.

The inner conductive layer 20 is a meandering wavy structure. The outer bottom film 10 is made from bisamino-polydimethylsiloxane because bis-amino-polydimethylsiloxane has good elasticity. Under external stretching stress, the outer bis-amino-polymethylsiloxane film is stretched, and the inner wavy conductive layer 20 is stretched as well. The conductive layer 20 is not broken within a certain stretch range, and the conductivity of the conductive layer 20 is not affected, either. When the stress disappears, the bisamino-polydimethylsiloxane film elastically shrinks, and the inner conductive layer 20 recovers its wave shape.

The flexible conductive of a sandwich structure imparts better protection and prevents the conductive layer 20 from being damaged by the mechanical external stress in the post-process of the actual product production. The flexible conductive film of a semi-sandwich structure may act as a conductive electrode on a whole surface.

The flexible conductive film and the method of producing the flexible conductive film will be introduced in detail with reference to specific embodiments.

### Embodiment 1

FIG. 2 illustrates a flexible conductive film 100 according to a first embodiment of the present disclosure. The flexible conductive film 100 includes a bottom film 10 and a conductive layer which is disposed on the bottom film 10. The conductive layer 20 and one side of the bottom film 10 near the conductive layer 20 are both wavy.

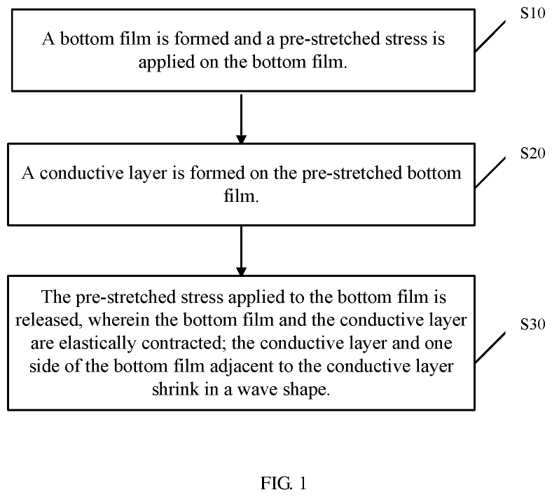

In FIG. 1, a method of producing the flexible conductive film 100 includes Block S10, Block S20, and Block S30.

At Block S10, a bottom film 10 is produced and a pre-stretched stress is applied on the bottom film 10.

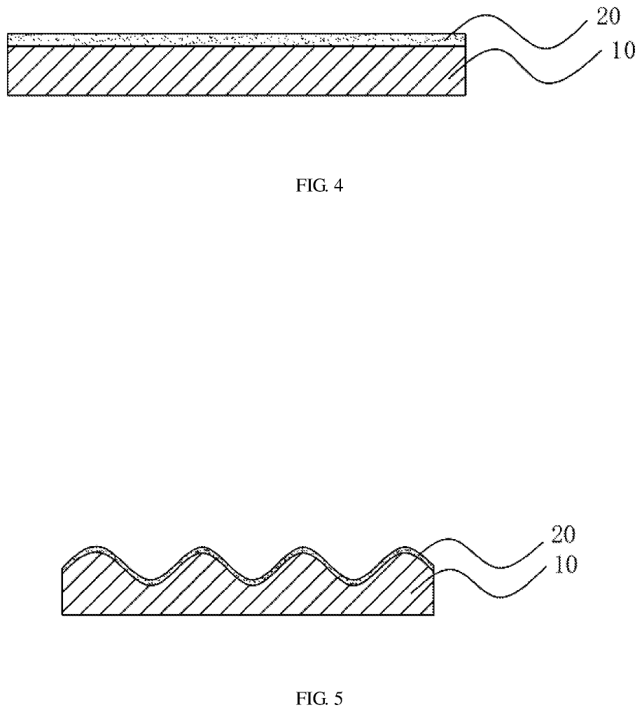

Please refer to FIG. 3 and FIG. 4. At first, a bisamino-dimethylsiloxane film serves as the bottom film 10. Next, the transparency of the bottom film 10 is adjusted by pre-stretched stress. So the transparency of the bottom film 10 reaches a set value, and the transparency of the bottom film 10 is controlled within a range of 55% to 88%. When the stretch ratio of the bottom film 10 is 50%, the transparency of the bottom film 10 is 75%.

At Block S20, a conductive layer 20 is formed on the pre-stretched bottom film 10.

At Block S20, a second conductive layer (not illustrated) is formed on the first conductive layer followed by a step of forming a first conductive layer (not illustrated) on the pre-stretched bottom film 10.

Firstly, a silver nanowire is produced, which can refer to the method of the related art. Next, the silver nanowire is transferred onto the pre-stretched bottom film 10 to form a first conductive layer. Afterwards, a mixture of 3,4-ethylenedioxythiophene (PEDOT) and polyphenylenesulfonic acid (PSS) is coated on the bottom film 10 by means of spin coating or inkjet printing to form a second conductive layer. The second conductive layer is a full-surface conductive film layer.

In FIG. 5, at Block S30, the pre-stretched stress applied to the bottom film 10 is released. The bottom film 10 and the conductive layer 20 are elastically contracted. The conductive layer 20 near the conductive layer 20 and one side of the bottom film 10 near the conductive layer 20 are both wavy on the surface.

The pre-stretched bisamino-polydimethylsiloxane film releases a certain external stress to cause elastic shrinkage. The upper surface of the bottom film 10 (i.e., the surface close to the conductive layer 20) forms a regular wave-like pleat in the stretching direction. The upper silver nanowire and the PSS/PEDOT film deposited on the film are both contracted and microscopic wavy wrinkles are formed.

After the product is complete subsequently, the flexible conductive film 100 with cracks when being used can react with mesitylene at room temperature to complete self-healing and crack recovery. The self-healing process requires manual addition of appropriate amount of tribenzaldehyde. The tribenzaldehyde can be manually added after the flexible conductive film 100 is produced completely, after the producing process, or when being used.

The conductive layer 20 formed with the producing method is of a wavy structure. Due to the buffering property of the physical structure, the wavy conductive layer 20 is not easily damaged by external stress and impairs its electrical conductivity when the flexible conductive film 100 is subjected to external stress, thereby extending the service life.

The flexible conductive film can be applied to a touch screen and a display panel. The embodiment further provides a display panel including a substrate and a flexible conductive film disposed on the substrate. The flexible conductive film can be produced by referring to the above producing method, which will not be detailed here again.

### Embodiment 2

In FIG. 6, a flexible conductive film further includes a protective layer 30 disposed on the conductive layer 20. The protective layer 30 covers the conductive layer 20.

In the present embodiment, a flexible protective layer is added on the basis of the producing method produced by the first embodiment. The flexible transparent material is formed to protect the upper and lower surfaces of the conductive layer 20.

Followed by Block S30, a step of producing another isamino-polydimethylsiloxane film identical to bottom film 10 is conducted. The isamino-polydimethylsiloxane film is laminated on the conductive layer 20 by molding to form a protective layer 30.

Similarly, the protective layer 30 with cracks can react with the meta-tribenzaldehyde at room temperature to complete self-healing and crack recovery.

The flexible conductive film in the present embodiment has two layers of flexible transparent material for protection, which can improve the stability of PEDOT/PSS when be used. The outer bottom film 10 and the protective layer 30 have self-healing properties so the micro-damage under the external stress can complete self-recovery at room temperature, thereby prolonging the service life.

### Embodiment 3

The structure of a flexible conductive film in a third embodiment is the same as the structure of the flexible conductive film in the first embodiment. The method of producing the flexible conductive film of the present embodiment includes Block S10, Block S20, and Block S30.

At Block S10, a bottom film is produced and a pre-stretched stress is applied on the bottom film.

A bisamino-dimethylsiloxane film serves as the bottom film. The transparency of the bottom film is adjusted by pre-stretched stress. The transparency of polyurethane elastomers is higher. Different types of polyurethane elastomers is chosen according to the transparency requirements of the bottom film.

At Block S20, a conductive layer is formed on the pre-stretched bottom film.

At first, the silver nanowire is transferred onto the pre-stretched bottom film to form a first conductive layer. Afterwards, a graphene oxide is produced by hummers method and a film is formed on the bottom film by a chemical reduction method to form a second conductive layer.

At Block S30, the pre-stretched stress applied to the bottom film is released. The bottom film and the conductive layer are elastically contracted. The conductive layer near the conductive layer and one side of the bottom film near the conductive layer are both wavy on the surface.

The bottom film that has been pre-stretched releases a certain external stretching force to cause elastic contraction. The silver nanowire and graphene oxide deposited on the bottom film contract with each other to be microscopically wavy.

Followed by Block S30 is a block of producing another layer of polyurethane elastomer, which is pressed onto the conductive layer with a molding method to form a protective layer. Two terminals of the conductive layer is conducted to form a flexible electrode with a sandwich-like structure.

The present disclosure brings advantageous effects as follows. The method of producing the flexible conductive film provided by the present disclosure can improve the flexibility and the stability of the conductive layer while the conductive layer is being used, thereby improving the service life of the flexible conductive film.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A method of producing a flexible conductive film, comprising:
a step S10 of producing a bottom film and applying a pre-stretched stress on the bottom film;
a step S20 of forming a conductive layer on the pre-stretched bottom film; and
a step of S30 of releasing the pre-stretched stress applied to the bottom film wherein the bottom film and the conductive layer are elastically contracted; the conductive layer and one side of the bottom film adjacent to the conductive layer shrink in a wave shape.

2. The producing method of claim 1 further comprising:
a step of S40 of forming a protective layer on the conductive layer.

3. The producing method of claim 1, wherein the step S20 comprises:
a step S201 of forming a first conductive layer on the pre-stretched bottom film;
a step S202 of forming a second conductive layer on the first conductive layer.

4. The producing method of claim 3, wherein a material for both of the first conductive layer and the second conductive layer is silver Nano, 3,4-ethylenedioxythiophene/polyphenylenesulfonic acid (PEDOT/PSS), or graphene oxide.

5. The producing method of claim 3, wherein the step S20 comprises:
a step S201 of producing a silver nanowire and transferring the silver nanowire onto the pre-stretched bottom film to form the first conductive layer;
a step S202 of coating a mixture of 3,4-ethylenedioxythiophene (PEDOT) and polyphenylenesulfonic acid (PSS) on the bottom film and make the mixture dry to form the second conductive layer.

6. The producing method of claim 2, wherein the structure of and the material for the protective layer is the same as the structure and material for the bottom film.

7. The producing method of claim 6, wherein the material for the bottom film is either bisamino-polydimethylsiloxane (H2N-PDMS-NH2) or polyurethane elastomer.

8. A flexible conductive film, comprising:
a bottom film;
a conductive layer, disposed on the bottom film;
wherein the conductive layer and one side of the bottom film near the conductive layer are both wavy.

9. The flexible conductive film of claim 8, wherein the conductive layer comprises a first conductive layer disposed on the bottom film and a second conductive layer disposed on the first conductive layer.

10. The flexible conductive film of claim 9, wherein the first conductive layer and the second conductive layer are both wavy.

11. The flexible conductive film of claim 9, wherein a material for both of the first conductive layer and the second conductive layer is silver Nano, 3,4-ethylenedioxythiophene/polyphenylenesulfonic acid (PEDOT/PSS), or graphene oxide.

12. The flexible conductive film of claim 8, wherein the flexible conductive film further comprises a protective layer disposed on the conductive layer.

13. The flexible conductive film of claim 12, wherein the structure of and the material for the protective layer is the same as the structure and material for the bottom film.

14. The flexible conductive film of claim 8, wherein the material for the bottom film is either bisamino-polydimethylsiloxane (H2N-PDMS-NH2) or polyurethane elastomer.

15. A display panel comprising:
a substrate;
a flexible conductive film disposed on the substrate, comprising:
a bottom film;
a conductive layer, disposed on the bottom film;
wherein the conductive layer and one side of the bottom film near the conductive layer are both wavy.

16. The display panel of claim 15, wherein the conductive layer comprises a first conductive layer disposed on the bottom film and a second conductive layer disposed on the first conductive layer.

17. The display panel of claim 16, wherein the first conductive layer and the second conductive layer are both wavy.

18. The display panel of claim 15, wherein the flexible conductive film further comprises a protective layer disposed on the conductive layer.

19. The display panel of claim 18, wherein the structure of and the material for the protective layer is the same as the structure and material for the bottom film.

20. The display panel of claim 15, wherein the material for the bottom film is either bisamino-polydimethylsiloxane (H2N-PDMS-NH2) or polyurethane elastomer.
